(19) United States
(12) Patent Application Publication
(10) Pub. No.: US 2007/0018252 A1
(43) Pub. Date: Jan. 25, 2007

(54) SEMICONDUCTOR DEVICE CONTAINING HIGH PERFORMANCE P-MOSFET AND/OR N-MOSFET AND METHOD OF FABRICATING THE SAME

(75) Inventor: Huilong Zhu, Poughkeepsie, NY (US)

Correspondence Address: SCULLY, SCOTT, MURPHY & PRESSNER, P.C., 400 GARDEN CITY PLAZA, Suite 300, GARDEN CITY, NY, 11530, US

(73) Assignee: INTERNATIONAL BUSINESS MACHINES CORPORATION, Armonk, NY (US)

(21) Appl. No.: 11/161,068

(22) Filed: Jul. 21, 2005

(51) Int. Cl. H01L 29/94

(52) U.S. Cl. 257/369

(57) ABSTRACT

The present invention relates to semiconductor devices that comprise at least one n-channel field effect transistor (n-FET) and/or at least one p-channel field effect transistor (p-FET). The n-FET contains a source region and a drain region with a tensilely stressed metal silicide surface layer, which applies tensile stress to the n-channel region of the n-FET. The p-FET contains a source region and a drain region with a compressively stressed metal silicide surface layer, which applies compressive stress to the p-channel region of the n-FET. Such tensilely and/or compressively stressed metal silicide surface layer(s) is formed by a salicidation process, during which correspondingly stressed sacrificial layer(s) is provided, so that the resulting metal silicide surface layer(s) retains the stress state(s) of the sacrificial layer(s) even after subsequent removal of such sacrificial layer(s).

### FIELD OF THE INVENTION

This invention relates to semiconductor devices containing high performance field effect transistors (FETs). More specifically, the present invention relates to semiconductor devices containing at least one high performance n-channel metal-oxide-semiconductor field effect transistor (n-MOSFET) and/or at least one high performance p-channel metal-oxide-semiconductor field effect transistor (p-MOSFET), and methods for fabricating such semiconductor devices.

### BACKGROUND OF THE INVENTION

Mechanical stresses within a semiconductor device substrate can be used to modulate device performance. For example, in silicon, hole mobility is enhanced when the silicon film is under compressive stress in the film direction and/or under tensile stress in a direction normal of the silicon film, while the electron mobility is enhanced when the silicon film is under tensile stress in the film direction and/or under compressive stress in the direction normal of the silicon film. Therefore, compressive and/or tensile stresses can be advantageously created in the channel regions of a p-MOSFET and/or an n-MOSFET in order to enhance the performance of such devices.

However, the same stress component, either compressive or tensile stress, discriminatively affects the performance of a p-MOSFET and an n-MOSFET. In other words, compressive stress in the source-drain direction and/or tensile stress in the direction normal of the gate dielectric layer enhances the performance of the p-MOSFET, but adversely impacts the performance of the n-MOSFET, while tensile stress in the source-drain direction and/or compressive stress in the direction normal of the gate dielectric layer enhances the performance of the n-MOSFET, but adversely impacts the performance of the p-MOSFET. Therefore, p-MOSFET and n-MOSFET require different types of stresses for performance enhancement, which imposes a challenge for concurrent fabrication of high performance p-MOSFET and n-MOSFET, due to the difficulty in concurrently applying compressive stress in the source-drain direction to the p-MOSFET and tensile stress to the n-MOSFET, or concurrently applying tensile stress in the direction normal of the gate dielectric surface to the p-MOSFET and compressive stress to the n-MOSFET.

One conventional approach for creating a desirable stressed silicon channel region is to form such a channel region upon a stress-inducing buffer layer. For example, a tensilely stressed silicon channel layer can be formed by epitaxially growing silicon over a thick, relaxed SiGe buffer layer. The lattice constant of germanium is about 4.2% greater than that of silicon, and the lattice constant of a silicon-germanium alloy is linear with respect to its germanium concentration. As a result, the lattice constant of a SiGe alloy with twenty atomic percent of germanium is about 0.8% greater than the lattice constant of silicon. Epitaxial growth of silicon on such a SiGe buffer layer will yield a silicon channel layer under tensile stress, with the underlying SiGe buffer layer being essentially unstrained, or “relaxed.”

The use of such a strain-inducing SiGe layer has several inherent disadvantages: (1) formation of relaxed SiGe buffer layer relies on defect formation, and consequentially, the SiGe material has a high defect density, which propagates into the silicon channel layer and poses significant challenges for device applications, such as control of leakage current and device yield, and (2) the presence of the SiGe layer in the device structure creates processing issues, such as deleterious diffusion of germanium into the strained silicon channel layer, high resistance silicide formation and altered dopant diffusion. Further, the strain-inducing SiGe layer can only be used to form a tensilely stressed silicon layer, which is useful only in forming high performance n-MOSFET devices, but not p-MOSFET devices.

Another conventional approach for creating desirable compressive and/or tensile stresses in the channel regions of the p-MOSFET and/or n-MOSFET devices is to cover the devices with compressively and/or tensilely stressed films, such as silicon nitride films. For example, U.S. Patent Application Publication No. 2003/0040158 published on Feb. 27, 2003 for “SEMICONDUCTOR DEVICE AND METHOD OF FABRICATING THE SAME” describes a semiconductor device that contains a first tensilely stressed nitride layer formed over the channel region of an n-MOSFET, and a second compressively stressed nitride layer formed over the channel region of a p-MOSFET, for respective application of tensile and compressive stresses to the n-MOSFET and p-MOSFET.

However, the aforementioned prior art semiconductor device incorporates additional structural layers, which result in increased device thickness and complexity. Further, the highly stressed nitride layers may detach from the semiconductor substrate and cause device failure.

There is a continuing need for improved semiconductor devices containing both high performance p-MOSFET and n-MOSFET components.

### SUMMARY OF THE INVENTION

The present invention advantageously employs intrinsically stressed sacrificial layers to selectively apply desired stresses to respective MOSFET components (i.e., compressive stress to p-MOSFETs and tensile stress to n-MOSFETs) during the source/drain salicidation process, so that the resulting source/drain metal silicide surface layers obtain intrinsic stresses by “memorizing” the corresponding stress states of the sacrificial layers. Moreover, the resulting source/drain metal silicide surface layers continue to apply desired stresses to the channel regions of the respective MOSFET components even after removal of the sacrificial layers.

In one aspect, the present invention relates to a semiconductor device comprising:

at least one n-channel field effect transistor (n-FET) comprising a source region, a drain region, a channel region, a gate dielectric layer, and a gate electrode, wherein the source and drain regions of the n-FET each contains a tensilely stressed metal silicide surface layer that applies tensile stress to the channel region of the n-FET; and/or

at least one p-channel field effect transistor (p-FET) comprising a source region, a drain region, a channel region, and a gate electrode, wherein the source and drain regions of the p-FET each contains a compressively stressed metal silicide surface layer that applies compressive stress to the channel region of the n-FET.

The term “stressed metal silicide surface layer(s)” as used herein refers to metal silicide surface layer(s) having intrinsic stress, either compressive or tensile, that is developed during preparation of such layers, rather than extrinsic stress applied to such layers by an external force after preparation of such layers.

In a preferred embodiment of the present invention, such a semiconductor device is devoid of any stressed nitride layer. Note that the term “stressed nitride layers” or “stressed nitride layer” as used herein refers to intrinsically stressed (i.e., with either intrinsic tensile or compressive stress) insulating layer(s), conductive layer(s), or semiconductor layer(s), which are removed after silicide formation.

The semiconductor device of the present invention uses stressed source/drain metal silicide surface layers to apply desired stresses/strains to the channel regions of the n-FET and p-FET, and it therefore does not require incorporation of additional structural layers, such as, the strain-inducing SiGe buffer layers mentioned hereinabove, or the stressed nitride layers as disclosed by U.S. Patent Application Publication No. 2003/0040158.

Alternatively, the invention of the present application may incorporate additional strain-inducing structures or methods that are known in the art, to achieve further performance enhancement for the n-FET and/or p-FET device(s).

In another aspect, the present invention relates to a semiconductor device that comprises at least one field effect transistor (FET) located on a semiconductor substrate, each FET having a source region, a drain region, a channel region, a gate dielectric layer, and a gate electrode, wherein the source and drain regions of the FET comprise tensilely or compressively stressed metal silicide surface layers that apply tensile or compressive stress to the channel region of the FET.

Specifically, when the semiconductor device comprises an n-channel FET, the source and drain regions of the n-channel FET comprise a tensilely stressed (in the source-drain direction) metal silicide surface layer that applies tensile stress in the source-drain direction to the channel region of the n-channel FET, which enhances electron mobility in such an n-channel FET. When the semiconductor device comprises a p-channel FET, the source and drain regions of the p-channel FET comprise a compressively stressed (in the source-drain direction) metal silicide surface layer that applies compressive stress in the source/drain direction to the channel region of the p-channel FET, which enhances hole mobility in such a p-channel FET.

In a further aspect, the present invention relates to a method for forming a semiconductor device that comprises at least one n-channel field effect transistor (n-FET) and/or at least one p-channel field effect transistor (p-FET), comprising:

providing at least one n-FET precursor structure, which comprises a source region, a drain region, a channel region, a gate dielectric layer, and a gate electrode, and/or at least one p-FET precursor structure, which comprises a source region, a drain region, a channel region, and a gate electrode;

forming a tensilely stressed metal silicide surface layer in the source and drain regions of the n-FET precursor structure and/or a compressively stressed metal silicide surface layer in the source and drain regions of the p-FET precursor structure by a salicidation process, during which a tensilely stressed sacrificial layer and/or a compressively stressed sacrificial layer is used for applying respective stress to the n-FET and/or the p-FET precursor structure(s); and

removing the tensilely and/or compressively stressed sacrificial layer(s) from the precursor structure(s) to form an n-FET and/or a p-FET,

wherein the tensilely stressed metal silicide surface layer in the source and drain regions of the n-FET applies tensile stress to the channel region of the n-FET, and/or wherein the compressively stressed metal silicide surface layer in the source and drain regions of the p-FET applies compressive stress to the channel region of the p-FET.

The salicidation process, as mentioned hereinabove, refers to a process for forming self-aligned metal silicide structures in the source, gate and drain regions of an FET device. For example, after deposition of a poly-silicon gate and exposure of source and drain regions for implantation and diffusion, metal can be deposited over the source, gate, and drain regions, preferably over a stressed layer that has been pre-deposited over the source, gate, and drain regions, and subsequently annealed to form metal suicides on these regions, and an etching step is then used to remove the stressed layer and unreacted metal while leaving the metal silicides.

Preferably, the salicidation process of the present invention comprises at least the following steps:

depositing a metal layer over the n-FET and/or p-FET precursor structure(s), wherein the metal layer comprises a metal or a metal alloy capable of reacting with silicon to form a metal silicide;

forming over the metal layer a tensilely stressed sacrificial layer and/or a compressively stressed sacrificial layer, wherein the tensilely stressed sacrificial layer selectively covers the n-FET precursor structure, and/or wherein the compressively stressed sacrificial layer selectively covers the p-FET precursor structure; and

annealing the n-FET and/or p-FET precursor structure(s) at an elevated temperature to form the tensilely stressed metal silicide surface layer in the source and drain regions of the n-FET precursor structure and/or the compressively stressed metal silicide surface layer in the source and drain regions of the p-FET precursor structure.

In still a further aspect, the present invention relates to a method for forming in a semiconductor substrate at least one n-channel field effect transistor (n-FET) or p-channel field effect transistor (p-FET), comprising:

providing at least one n-FET or p-FET precursor structure that comprises a source region, a drain region, a channel region, a gate dielectric layer, and a gate electrode;

forming a tensilely or compressively stressed metal silicide surface layer in the source and drain regions of the n-FET or p-FET precursor structure by a salicidation process, during which a tensilely or compressively stressed sacrificial layer is used for applying respective stress to the n-FET or p-FET precursor structure;

removing the tensilely or compressively stressed sacrificial layer from the precursor structure to form an n-FET or p-FET,

wherein the tensilely or compressively stressed metal silicide surface layer in each of the source and drain regions of the n-FET or p-FET applies tensile or compressive stress to the channel region of the n-FET or p-FET.

Specifically, for forming an n-FET, a tensilely stressed sacrificial layer is employed during the salicidation process to apply tensile stress to an n-FET precursor structure, and for forming a p-FET, a compressively stressed sacrificial layer is employed instead for applying compressive stress to a p-FET precursor structure.

Other aspects, features and advantages of the invention will be more fully apparent from the ensuing disclosure and appended claims.

### BRIEF DESCRIPTION OF THE DRAWINGS

FIGS. 1-8 are cross sectional views that illustrate the processing steps for forming an exemplary semiconductor device that comprises an n-MOSFET with a tensilely stressed metal suicide surface layer in the source/drain regions and a p-MOSFET with a compressively stressed metal silicide surface layer in the source/drain regions, according to one embodiment of the present invention.

### DETAILED DESCRIPTION OF THE INVENTION AND PREFERRED EMBODIMENTS THEREOF

U.S. Patent Application Publication No. 2005/0082616 published on Apr. 21, 2005 for “HIGH PERFORMANCE STRESS-ENHANCED MOSFETS USING SI:C AND SIGE EPITAXIAL SOURCE/DRAIN AND METHOD OF MANUFACTURE” and U.S. Patent Application Publication No. 2003/0040158 published on Feb. 27, 2003 for “SEMICONDUCTOR DEVICE AND METHOD OF FABRICATING THE SAME” are incorporated herein by reference in their entireties for all purposes.

As mentioned hereinabove, the present invention uses intrinsically stressed sacrificial layers during the source/drain salicidation process to apply desired stresses (either tensile or compressive) to n-MOSFET and p-MOSFET devices. The resulting source/drain metal silicide surface layers, which are formed under the stresses applied by the sacrificial layers, can “memorize” the stress states of the sacrificial layers, i.e., they obtain intrinsic stresses corresponding to the stresses applied by the sacrificial layers, and can therefore be used to apply the desired stresses to the channel regions of the respective MOSFET devices after removal of the sacrificial layers.

The present invention distinguishes over the disclosure by U.S. Patent Application Publication No. 2003/0040158 in the following aspects: The present invention employs stressed sacrificial layers, which preferably comprise intrinsically stressed silicon nitride, during the source/drain salicidation process, i.e., such stressed sacrificial layers are provided after deposition of the metal layer, but before the annealing step in the salicidation process. In contrast, U.S. Patent Application Publication No. 2003/0040158 discloses deposition of stressed silicon nitride layers after the source/drain salicidation process is completed;

The present invention provides intrinsically stressed source/drain metal silicide surface layers, which are formed by the source/drain salicidation process under the impact of the stressed sacrificial layers. In contrast, U.S. Patent Application Publication No. 2003/0040158 only discloses source/drain metal silicide layers that are not intrinsically stressed, i.e., such source/drain metal silicide layers are formed before deposition of the stressed silicon nitride layers and therefore do not contain intrinsic stress; and

The present invention uses the intrinsically stressed source/drain metal silicide surface layers to apply desired stresses to the channel regions of the n-MOSFET and the p-MOSFET, while the stressed sacrificial layers are removed after formation of the intrinsically stressed source/drain metal silicide surface layers. In contrast, U.S. Patent Application Publication No. 2003/0040158 uses the stressed silicon nitride layers to apply desired stresses to the channel regions of the n-MOSFET and the p-MOSFET. Therefore, operation of the n-MOSFET and the p-MOSFET devices as disclosed by U.S. Patent Application Publication No. 2003/0040158 depend on the presence of such stressed silicon nitride layers, which therefore are not and cannot be subsequently removed.

In the following description, numerous specific details are set forth, such as particular structures, components, materials, dimensions, processing steps and techniques, in order to provide a thorough understanding of the present invention. However, it will be appreciated by one of ordinary skill in the art that the invention may be practiced without these specific details. In other instances, well-known structures or processing steps have not been described in detail in order to avoid obscuring the invention.

It will be understood that when an element as a layer, region or substrate is referred to as being “on” another element, it can be directly on the other element or intervening elements may also be present. In contrast, when an element is referred to as being “directly on” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

The present invention provides a method for forming a semiconductor device that comprises at least one n-MOSFET with a tensilely stressed source/drain metal silicide surface layer and/or at least one p-MOSFET with a compressively stressed source/drain metal silicide surface layer. The tensilely and/or compressively stressed source/drain metal silicide surface layer(s), in turn, applies respective stress to the channel region(s) of the n-MOSFET and/or the p-MOSFET, to enhance mobility of the corresponding carrier(s) in such channel region(s) (i.e., electrons in the n-channel and/or holes in the p-channel).

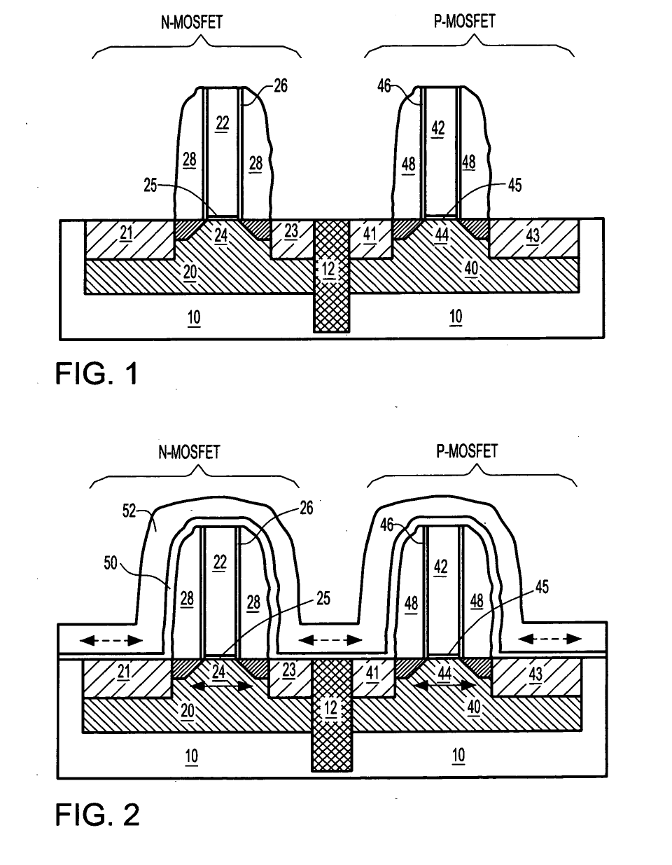

Such a method, as well as the resulting semiconductor device structure, will now be described in greater detail by referring to the accompanying drawings in FIGS. 1-8. Note that in these drawings, which are not drawn to scale, like and/or corresponding elements are referred to by like reference numerals. It is further noted that in the drawings only one n-MOSFET and one p-MOSFET are shown atop a single semiconductor substrate. Although illustration is made to such an embodiment, the present invention is not limited to the formation of any specific number of MOSFET devices on the surface of the semiconductor structure.

Reference is first made to FIG. 1, which shows an n-MOSFET precursor structure and a p-MOSFET precursor structure formed in a semiconductor substrate 10 by various well known front-end-of-line processing steps.

The semiconductor substrate 10 may comprise any semiconductor material including, but not limited to: Si, SiC, SiGe, SiGeC, Ge alloys, GaAs, InAs, InP, as well as other III-V or II-VI compound semiconductors. Semiconductor substrate 10 may also comprise an organic semiconductor or a layered semiconductor such as Si/SiGe, a silicon-on-insulator (SOI) or a SiGe-on-insulator (SGOI). In some embodiments of the present invention, it is preferred that the semiconductor substrate 10 be composed of a Si-containing semiconductor material, i.e., a semiconductor material that includes silicon. The semiconductor substrate 10 may be doped, undoped or contain doped and undoped regions therein. The semiconductor substrate 10 may include a first doped (n- or p-) device region 20 for the n-MOSFET, and a second doped (n- or p-) device region 40 for the p-MOSFET. The first doped device region 20 and the second doped device region 20 may have the same or different conductivities and/or doping concentrations. The doped device regions 20 and 40 are typically known as “wells”.

At least one isolation region 12 is typically formed into the semiconductor substrate 10, to provide isolation between the doped device regions 20 and 40. The isolation region 12 may be a trench isolation region or a field oxide isolation region. The trench isolation region is formed utilizing a conventional trench isolation process well known to those skilled in the art. For example, lithography, etching and filling of the trench with a trench dielectric may be used in forming the trench isolation region. Optionally, a liner may be formed in the trench prior to trench fill, a densification step may be performed after the trench fill and a planarization process may follow the trench fill as well. The field oxide may be formed utilizing a so-called local oxidation of silicon process.

After forming the at least one isolation region 12 within the semiconductor substrate 10, a gate dielectric layer (not shown) is formed on the entire surface of the structure 10. The gate dielectric layer can be formed by a thermal growing process such as, for example, oxidation, nitridation or oxynitridation. Alternatively, the gate dielectric layer can be formed by a deposition process such as, for example, chemical vapor deposition (CVD), plasma-assisted CVD, atomic layer deposition (ALD), evaporation, reactive sputtering, chemical solution deposition and other like deposition processes. The gate dielectric layer may also be formed utilizing any combination of the above processes.

The gate dielectric layer is comprised of an insulating material including, but not limited to: an oxide, nitride, oxynitride and/or silicate including metal silicates and nitrided metal silicates. In one embodiment, it is preferred that the gate dielectric layer is comprised of an oxide such as, for example, SiO₂, HfO₂, ZrO₂, Al₂O₃, TiO₂, La₂O₃, SrTiO₃, LaAlO₃, and mixtures thereof.

The physical thickness of the gate dielectric layer may vary, but typically, the gate dielectric layer has a thickness from about 0.5 to about 10 nm, with a thickness from about 0.5 to about 3 nm being more typical.

After forming the gate dielectric layer, a blanket layer of polysilicon (not shown) is formed on the gate dielectric layer, utilizing a known deposition process such as, for example, physical vapor deposition, CVD or evaporation. The blanket layer of polysilicon may be doped or undoped. If doped, an in-situ doping deposition process may be employed in forming the same. Alternatively, a doped polysilicon layer can be formed by deposition, ion implantation and annealing. The thickness, i.e., height, of the polysilicon layer deposited at this point of the present invention may vary depending on the deposition process employed. Typically, the polysilicon layer has a vertical thickness from about 20 to about 180 nm, with a thickness from about 40 to about 150 nm being more typical.

The gate dielectric layer and the polysilicon layer jointly form a polysilicon gate stack layer (not shown), which may comprise additional structure layers, e.g., cap layers and/or diffusion barrier layers, as commonly included in MOS gate structures. After formation of the polysilicon gate stack layer, a dielectric hard mask (not shown) is deposited over the polysilicon gate stack layer utilizing a deposition process such as, for example, physical vapor deposition or chemical vapor deposition. The dielectric hard mask may be an oxide, nitride, oxynitride or any combination thereof.

The polysilicon gate stack layer and the dielectric hard mask are then patterned by lithography and etching so as to provide two or more patterned gate stacks, one for the n-MOSFET and one for the p-MOSFET as shown in FIG. 1. The patterned gate stack for the n-MOSFET contains the polysilicon gate electrode 22 and the gate dielectric layer 25, and the patterned gate stack for the p-MOSFET contains the polysilicon gate electrode 42 and the gate dielectric layer 45. The patterned gate stacks may have the same dimension, i.e., length, or they can have variable dimensions to improve device performance. The lithography step includes applying a photoresist (not shown) to the upper surface of the dielectric hard mask layer, exposing the photoresist to a desired pattern of radiation and developing the exposed photoresist utilizing a conventional resist developer. The pattern in the photoresist is then transferred to the dielectric mask layer and the polysilicon gate stack layer utilizing one or more dry etching steps, forming the patterned gate stacks. Suitable dry etching processes that can be used in the present invention in forming the patterned gate stacks include, but are not limited to: reactive ion etching (RIE), ion beam etching, plasma etching or laser ablation. The patterned photoresist is then removed after etching has been completed.

A reoxidation process can optionally, but not necessarily, be performed to create a conformal silicon oxide sidewall layer (not shown) over the patterned polysilicon gate stacks as mentioned hereinabove. Next, a conformal silicon nitride layer is deposited over the entire structure. The conformal silicon dioxide sidewall layer and the silicon nitride layer can then be patterned to form sidewall oxide liners 26, 46 and sidewall nitride spacers 28, 48 along exposed sidewalls of the patterned gate stacks, as shown in FIG. 1. Patterning of the conformal silicon dioxide sidewall layer and the silicon nitride layer is achieved by utilizing an etching process that selectively removes nitride. A second etching step can be performed to expose the surface of the substrate 10.

After formation of the sidewall oxide liners 26, 46 and the sidewall nitride spacers 28, 48, p-doped source and drain regions 21 and 23 and n-doped source and drain regions 41 and 43 are formed into the semiconductor substrate 10. The p-doped source/drain regions 21 and 23, together with an n-type channel region 24 therebetween, define the active region of the n-MOSFET, while the n-doped source/drain regions 21 and 23, together with a p-type channel region 44 therebetween, define the active region of the p-MOSFET.

The source/drain regions 21, 23, 41, and 43 can be formed by ion implantation, followed by a subsequent annealing step to activate the dopant species implanted in the source/drain regions 21, 23, 41, and 43. The conditions for the ion implantation and the annealing step are well known to those skilled in the art.

The source/drain regions 21, 23, 41, and 43 may contain embedded epitaxial layers with intrinsic tensile or compressive stress, as described in U.S. Patent Application Publication No. 2005/0082616. It is known that epitaxial growth of a material layer on a substrate may impart intrinsic stress to such material layer, if the natural lattice constant of such a material layer is different from the base lattice constant of the substrate. For example, the natural lattice constant of carbon is smaller than that of silicon. Therefore, a Si:C layer epitaxially grown on a silicon substrate contains tensile stress due to tensile distortion of the Si:C crystal lattice. Similarly, the natural lattice constant of germanium is larger than that of silicon, so a SiGe layer epitaxially grown on a silicon substrate contains compressive stress due to compressive distortion of the SiGe crystal lattice.

U.S. Patent Application Publication No. 2005/0082616 specifically describes use of embedded Si:C or SiGe layers with tensile or compressive stress in the source/drain regions of n-FET or p-FET for providing tensile or compressive stress in the n-FET or p-FET channel. For example, the source and drain regions of a p-FET are first etched, and a highly compressive selective epitaxial SiGe layer is grown in the etched regions of the p-FET to apply compressive stress to the adjacent p-FET channel region. Subsequently, the source and drain regions of an n-FET are etched, and a highly tensile selective epitaxial Si:C layer is grown in the etched regions of the n-FET to apply tensile stress to the adjacent n-FET channel region. For more details, please see U.S. Patent Application Publication No. 2005/0082616, the content of which is hereby incorporated by reference in its entirety for all purposes.

FIGS. 2-7 show a salicidation process for forming metal silicide contacts in the source, drain, and gate regions of the n-MOSFET and p-MOSFET. Specifically, the salicidation process forms a tensilely stressed metal silicide surface layer in the source and drain regions of the n-MOSFET and a compressively stressed metal silicide surface layer in the source and drain regions of the p-MOSFET, by using a stress memorization technique, which is to be described in greater details hereinafter.

First, a metal layer 50 and a tensilely stressed sacrificial layer 52 are deposited over the entire structure, as shown in FIG. 2. It is noted that when the substrate 10 does not include silicon, a silicon layer (not shown) can be formed atop the non silicon-containing substrate prior to metal layer 50 deposition.

The metal used in forming the metal layer 50 comprises any metal or metal alloy that is capable of reacting with silicon to form a metal silicide. Examples of such metals or metal alloys include, but are not limited to: Ti, Ta, W, Co, Ni, Pt, Pd and alloys thereof. In one embodiment, Ni is a preferred metal. In another embodiment, Pt, Co, or Ti is preferred. The metal layer 50 may be deposited using any conventional deposition process including, for example, sputtering, chemical vapor deposition, evaporation, chemical solution deposition, atomic layer deposition (ALD), plating and the like. Preferably, the metal layer 50 has a thickness ranging from about 1 nm to about 50 nm, more preferably from about 2 nm to about 20 nm, and most preferably from about 5 nm to about 15 nm.

The tensilely stressed sacrificial layer 52, which preferably comprises an insulating material, such as silicon nitride, or any suitable conductive or semiconductive material, can be formed by, for example, a low pressure chemical vapor deposition (LPCVD) process or a plasma enhanced chemical vapor deposition (PECVD) process, as disclosed by U.S. Patent Application Publication No. 2003/0040158 or by A. Tarraf et al., “Stress Investigation of PECVD Dielectric Layers for Advanced Optical MEMS,” J. MICROMECH. MICROENG., Vol. 14, pp. 317-323 (2004), or by any other suitable deposition techniques well known in the art. Preferably, the tensilely stressed sacrificial layer 52 has a thickness ranging from about 10 nm to about 500 nm, more preferably from about 20 nm to about 200 nm, and most preferably from about 40 nm to about 100 nm.

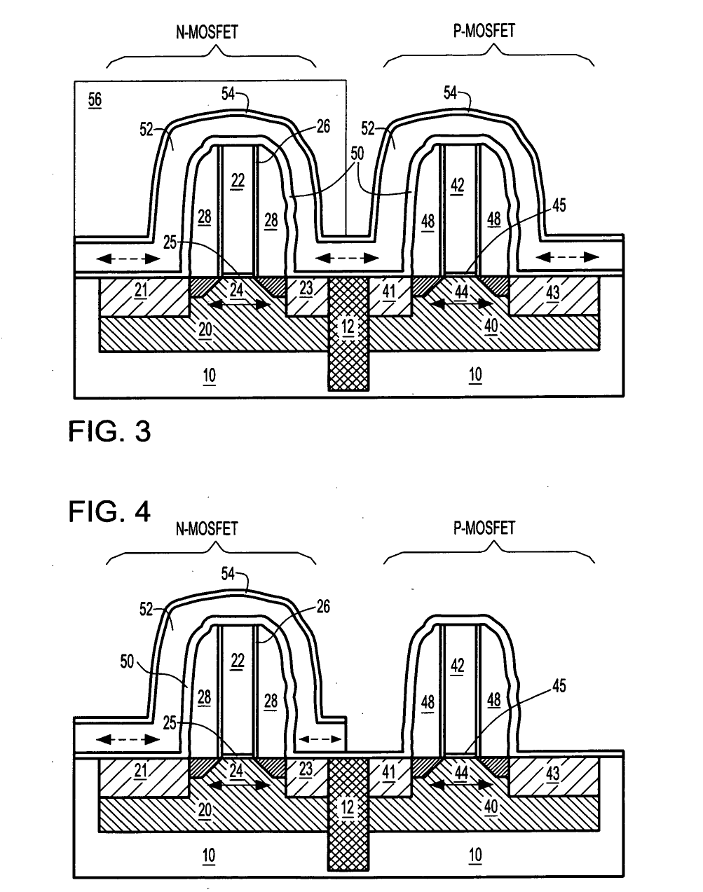

Then, an oxide liner 54 is formed over the tensilely stressed sacrificial layer 52 to cover the entire structure of FIG. 2, followed by formation of a patterned photoresist film 56 over the n-MOSFET. The oxide liner 54 has a thickness ranging from about 0.5 nm to about 40 nm, more preferably from about 1 nm to about 20 nm, and most preferably from about 5 nm to about 10 nm. The area corresponding to the p-MOSFET and other necessary areas are selectively exposed, as shown in FIG. 3.

As shown in FIG. 4, the patterned photoresist film 56 is used as a mask for selectively removal of a portions of the oxide liner 54 by an etching step, preferably by a dry etching process such as reactive ion etching (RIE). The patterned photoresist film 56 is then removed from the n-MOSFET, and the oxide liner 54 is used as a mask for selectively removing a portion of the tensilely stressed sacrificial layer 52 from the p-MOSFET via isotropic etching. Therefore, the surface of the metal layer 50 is exposed in the p-MOSFET area.

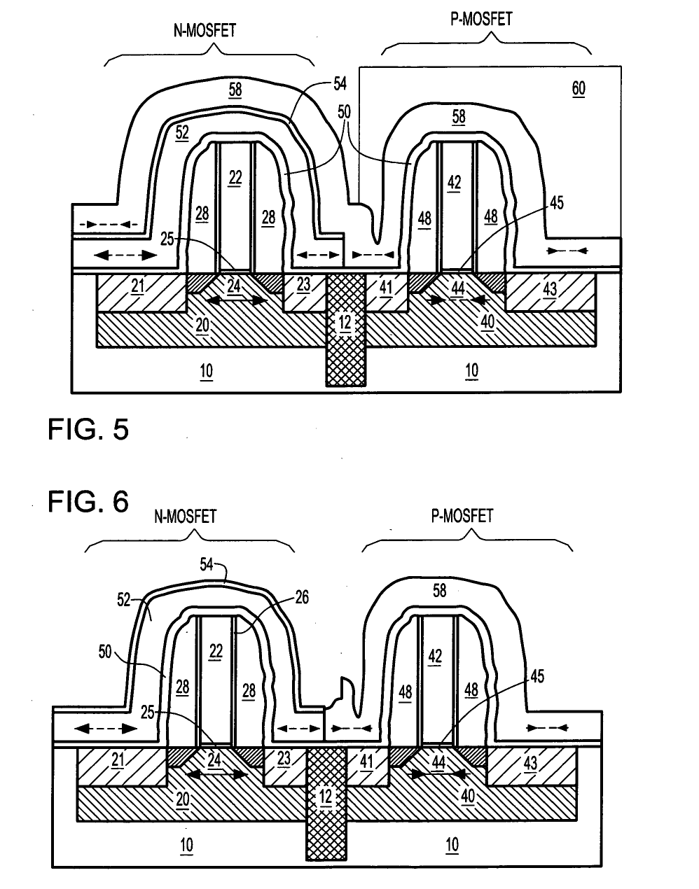

Subsequently, a compressively stressed sacrificial layer 58, which also preferably comprises an insulating material, such as silicon nitride, or any other suitable conductive or semiconductive material, is deposited over the entire structure of FIG. 4, followed by formation of a patterned photoresist layer 60 over the p-MOSFET, as shown in FIG. 5.

The compressively stressed sacrificial layer 58 can be formed by, for example, a plasma enhanced chemical vapor deposition (PECVD) process, as disclosed by U.S. Patent Application Publication No. 2003/0040158 or by A. Tarraf et al., “Stress Investigation of PECVD Dielectric Layers for Advanced Optical MEMS,” J. MICROMECH. MICROENG., Vol. 14, pp. 317-323 (2004), or by any other suitable deposition techniques well known in the art such as high density plasma (HDP) deposition. Preferably, the compressively stressed sacrificial layer 52 has a thickness ranging from about 10 nm to about 500 nm, more preferably from about 20 nm to about 200 nm, and most preferably from about 30 nm to about 150 nm.

The patterned photoresist layer 60 selectively exposes the area corresponding to the n-MOSFET and other necessary areas and therefore can be used as a mask for selectively removing a portion of the compressively stressed sacrificial layer 58 from the n-MOSFET by isotropic etching. The patterned photoresist film 56 is removed from the p-MOSFET after the etching step.

Thus, the tensilely stressed sacrificial layer 52 selectively covers and applies tensile stress to the n-MOSFET, while the compressively stressed sacrificial layer 58 selectively covers and applies compressive stress to the p-MOSFET, as shown in FIG. 6.

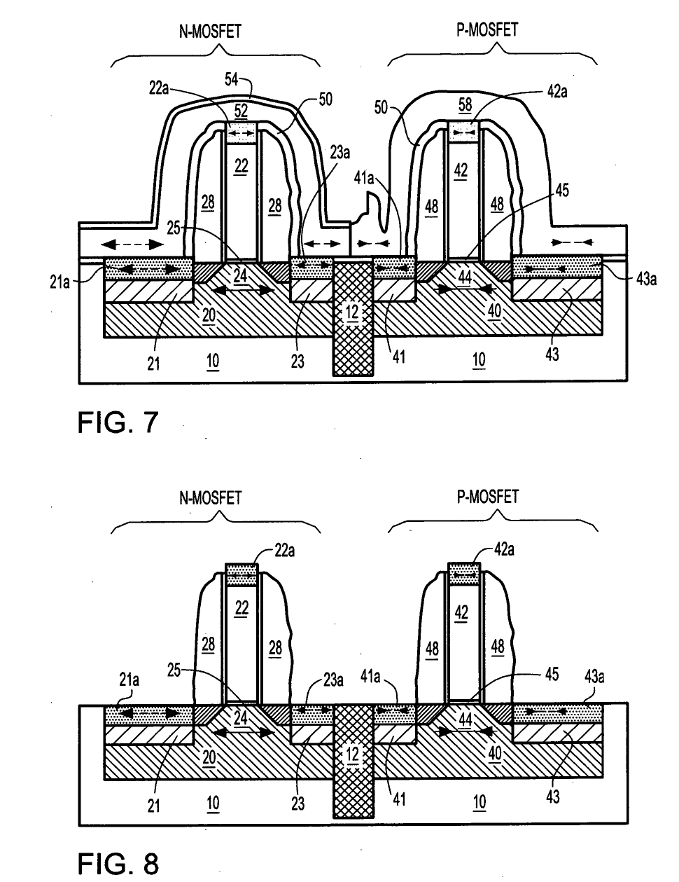

An annealing step is then carried out to form metal silicide surface layers 21a, 23a, 22a, 41a, 43a, and 42a in the source/drain and gate regions of the n-MOSFET and p-MOSFET, as shown in FIG. 7.

The annealing is typically performed in a gas atmosphere, e.g., He, Ar, N₂ or forming gas at relatively low temperatures ranging from about 100° C. to about 600° C., preferably from about 300° C. to about 500° C., and most preferably from about 300° C. to about 450° C., by using a continuous heating regime or various ramp and soak heating cycles.

The low temperature annealing step preserves the stresses in the sacrificial layers 52 and 58 and results in metal silicide surface layers that “memorize” the corresponding stress state of the adjacent sacrificial layer. For example, under the tensile stress applied by the overlaying sacrificial layer 52, the source/drain metal silicide layers 21a, 23a and the gate metal silicide layers 22a for the n-MOSFET obtain intrinsic tensile stress during the annealing step, i.e., they “memorize” the tensile stress of the overlaying sacrificial layer 52. Similarly, under the compressive stress applied by the overlaying sacrificial layer 58, the source/drain metal silicide layers 41a, 43a and the gate metal silicide layers 42a for the p-MOSFET obtain intrinsic compressive stress during the annealing step, i.e., they “memorize” the compressive stress of the overlaying sacrificial layer 58.

The stress memorization technique, as described hereinabove, allows subsequently removal of the stressed sacrificial layers 52 and 58 from the resulting n-MOSFET and p-MOSFET devices, as shown in FIG. 8, since the properly stressed source/drain metal silicide layers can now apply desired stress to the channel regions of the n-MOSFET and the p-MOSFET, and the sacrificial layers 52 and 58 are therefore no longer necessary and can be removed.

Subsequently, conventional back-end-of-line processing steps, which are not described herein in detail, can be carried out to form a complete semiconductor device containing both the n-MOSFET and the p-MOSFET.

It should be noted that although the above-described processing steps illustrate formation of the tensilely stressed sacrificial layer before the compressively stressed sacrificial nitride layer, the present invention is not limited to such a specific order. In other words, the compressively stressed sacrificial layer can be readily formed before deposition of the tensilely stressed sacrificial layer in the practice of the present invention.

Further, although the above-described FET structures do not include raised source/drain regions, the present invention also contemplates the presence of raised source/drain regions in the FET structures. The raised source/drain regions are formed utilizing conventional techniques well known to those skilled in the art. Specifically, the raised source/drain regions are formed by depositing any Si-containing layer, such as epitaxial Si, amorphous Si, SiGe, and the like, atop the semiconductor substrate 10 prior to implanting.

The methods of the present invention can be widely used for fabricating various semiconductor device structures, including, but not limited to, complementary metal-oxide-semiconductor (CMOS) transistors, as well as integrated circuit, microprocessors and other electronic devices comprising such CMOS transistors, which are well known to those skilled in the art and can be readily modified to incorporate the strained semiconductor-on-insulator structure of the present invention, and therefore details concerning their fabrication are not provided herein.

While the invention has been described herein with reference to specific embodiments, features and aspects, it will be recognized that the invention is not thus limited, but rather extends in utility to other modifications, variations, applications, and embodiments, and accordingly all such other modifications, variations, applications, and embodiments are to be regarded as being within the spirit and scope of the invention.

What is claimed is:

1. A semiconductor device comprising:
at least one n-channel field effect transistor (n-FET) comprising a source region, a drain region, a channel region, a gate dielectric layer, and a gate electrode, wherein the source and drain regions of said n-FET each contains a tensilely stressed metal silicide surface layer that applies tensile stress to the channel region of said n-FET; and/or
at least one p-channel field effect transistor (p-FET) comprising a source region, a drain region, a channel region, and a gate electrode, wherein the source and drain regions of said p-FET each contains a compressively stressed metal silicide surface layer that applies compressive stress to the channel region of said n-FET.

2. The semiconductor device of claim 1, devoid of any stressed silicon nitride layer.

3. The semiconductor device of claim 1, wherein the n-FET and the p-FET are located in a semiconductor substrate and are separated from each other by at least one isolation region.

4. The semiconductor device of claim 3, wherein the source and drain regions of the n-FET further contain an embedded layer of material that has an intrinsic lattice constant smaller than a base lattice constant of the semiconductor substrate so as to create tensile stress in the channel region of the n-FET.

5. The semiconductor device of claim 4, wherein the source and drain regions of the n-FET contain an embedded Si:C layer.

6. The semiconductor device of claim 3, wherein the source and drain regions of the p-FET further contain an embedded layer of material that has an intrinsic lattice constant larger than a base lattice constant of the semiconductor substrate so as to create compressive stress in the channel region of the p-FET.

7. The semiconductor device of claim 6, wherein the source and drain regions of the p-FET contain an embedded SiGe layer.

8. A semiconductor device comprising at least one field effect transistor (FET) formed in a semiconductor substrate, said at least one FET having a source region, a drain region, a channel region, a gate dielectric layer, and a gate electrode, wherein the source and drain regions of said FET each comprise a tensilely or compressively stressed metal silicide surface layer that applies tensile or compressive stress to the channel region of said FET.

9. The semiconductor device of claim 8, devoid of any stressed silicon nitride layer.

10. The semiconductor device of claim 8, wherein said at least one FET is an n-channel FET having source and drain regions with a tensilely stressed metal silicide surface layer.

11. The semiconductor device of claim 10, wherein the source and drain regions of said n-channel FET further comprise an embedded layer of material that has an intrinsic lattice constant smaller than a base lattice constant of a semiconductor substrate so as to create tensile stress in the channel region of said n-channel FET.

12. The semiconductor device of claim 11, wherein the source and drain regions of the n-channel FET comprise an embedded Si:C layer.

13. The semiconductor device of claim 8, wherein said at least one FET is a p-channel FET having source and drain regions with a compressively stressed metal silicide surface layer.

14. The semiconductor device of claim 12, wherein the source and drain regions of said p-channel FET further comprise an embedded layer of material that has an intrinsic lattice constant larger than a base lattice constant of a semiconductor substrate so as to create compressive stress in the channel region of said p-channel FET.

15. The semiconductor device of claim 14, wherein the source and drain regions of the p-channel FET comprise an embedded SiGe layer.

16. A method for forming a semiconductor device that comprises at least one n-channel field effect transistor (n-FET) and at least one p-channel field effect transistor (p-FET), comprising:
providing at least one n-FET precursor structure, which comprises a source region, a drain region, a channel region, a gate dielectric layer, and a gate electrode, and/or at least one p-FET precursor structure, which comprises a source region, a drain region, a channel region, and a gate electrode;
forming a tensilely stressed metal silicide surface layer in the source and drain regions of the n-FET precursor structure, and/or a compressively stressed metal silicide surface layer in the source and drain regions of the p-FET precursor structure by a salicidation process, during which a tensilely stressed sacrificial layer and/or a compressively stressed sacrificial layer is used for applying respective stress to the n-FET and/or the p-FET precursor structure(s); and
removing the tensilely and/or compressively stressed sacrificial layer(s) from the precursor structure(s) to form an n-FET and/or a p-FET,
wherein the tensilely stressed metal silicide surface layer in the source and drain regions of the n-FET applies tensile stress to the channel region of said n-FET, and/or wherein the compressively stressed metal silicide surface layer in the source and drain regions of the p-FET applies compressive stress to the channel region of said p-FET.

17. The method of claim 16, wherein the salicidation process comprises:
depositing a metal layer over the precursor structure(s), wherein said metal layer comprises a metal or a metal alloy capable of reacting with silicon to form a metal silicide;
forming over the metal layer a tensilely stressed sacrificial layer and/or a compressively stressed sacrificial layer, wherein the tensilely stressed sacrificial layer selectively covers the n-FET precursor structure, and/or wherein the compressively stressed sacrificial layer selectively covers the p-FET precursor structure; and
annealing the precursor structure(s) at an elevated temperature to form the tensilely stressed metal silicide surface layer in the source and drain regions of the n-FET precursor structure and/or the compressively stressed metal silicide surface layer in the source and drain regions of the p-FET precursor structure.

18. A method for forming in a semiconductor substrate at least one n-channel field effect transistor (n-FET) or p-channel field effect transistor (p-FET), comprising:
providing at least one n-FET or p-FET precursor structure that comprises a source region, a drain region, a channel region, a gate dielectric layer, and a gate electrode;
forming a tensilely or compressively stressed metal silicide surface layer in the source and drain regions of said n-FET or p-FET precursor structure by a salicidation process, during which a tensilely or compressively stressed sacrificial layer is used for applying respective stress to the n-FET or p-FET precursor structure; and
removing the tensilely or compressively stressed sacrificial layer from the precursor structure to form an n-FET or p-FET,
wherein the tensilely or compressively stressed metal silicide surface layer in the source and drain regions of said n-FET or p-FET applies tensile or compressive stress to the channel region of said n-FET or p-FET.

19. The method of claim 18, wherein the salicidation process comprises:
depositing a metal layer over the n-FET or p-FET precursor structure, wherein said metal layer comprises a metal or a metal alloy capable of reacting with silicon to form a metal silicide;
forming over the metal layer a tensilely or compressively stressed sacrificial layer to cover the n-FET or p-FET precursor structure; and
annealing the n-FET or p-FET precursor structure at an elevated temperature to form the tensilely or compressively stressed metal silicide surface layer in the source and drain regions of the n-FET or p-FET precursor structure.

20. The method of claim 18, wherein an n-FET having source and drain regions with a tensilely stressed metal silicide surface layer is formed, and wherein a tensilely stressed sacrificial layer is used during the salicidation process for applying tensile stress to the n-FET precursor structure.
